(19) United States
(12) Patent Application Publication
(10) Pub. No.: US 2008/0249727 A1
(43) Pub. Date: Oct. 9, 2008

(54) Systems and Methods for Determining Variations in Voltages Applied to an Integrated Circuit Chip

(76) Inventor: Satoru Takase, Kanagawa (JP)

Correspondence Address: LAW OFFICES OF MARK L. BERRIER, 3811 BEE CAVES ROAD, SUITE 204, AUSTIN, TX, 78746, US

(21) Appl. No.: 11/696,381

(22) Filed: Apr. 4, 2007

(51) Int. Cl. G01R 19/00

(52) U.S. Cl. 702/64

(57) ABSTRACT

Systems and methods for determining local voltages provided by a power distribution network to an integrated circuit chip by applying an external voltage to a power distribution network, firing a set of current sources distributed across the chip and measuring local voltages on the chip. The current sources may, for example, comprise a clock tree carrying a free-running clock signal, or multiple individual current source structures. The voltages may be measured, for instance, by units comprising voltage controlled oscillators (VCO's) coupled to counters which determine the corresponding oscillation frequencies and registers which store the resulting oscillation counts. The measured voltages may be used to identify non-uniformities in the voltage applied across the chip, as well as to determine local differences in the resistance of the power distribution network.

### BACKGROUND

1. Field of the Invention

The invention relates generally to the design of integrated circuits, and more particularly to systems and methods for determining local voltages provided by a power distribution network to an integrated circuit chip.

2. Related Art

Integrated circuits contain many individual electronic components, such as transistors, resistors, capacitors, diodes, and the like, which are arranged and interconnected to form larger components, such as logic gates, memory cells, sense amplifiers, etc. These components form even larger components, such as processor cores, bus controllers, and so on, which are used to build devices such as computers, cell phones, PDAs, etc. These electrical components and devices, however, cannot operate without power. It is therefore necessary, when constructing these components and devices, to provide a power distribution network that can supply power from a source which is an external to the integrated circuit to each of the on-chip components of the integrated circuit.

Typically, a power distribution network in an integrated circuit includes multiple metal layers and multiple layers of vias that interconnect the metal layers. The power distribution network also includes contacts for connection to the external power source, as well as contacts to the components of the integrated circuit. Conventionally, each metal layer includes traces that are oriented in a single direction, and the traces of successive metal layers are oriented in different (perpendicular) directions. Power supplied to the power distribution network at a given contact can therefore be transmitted to a wider area on the chip by connecting the contact to a first trace which extends in one direction, and then connecting the first trace to further traces which extend in the other direction, and so on through the different layers of the power distribution network.

Since the power distribution network of the integrated circuit has its own inherent electrical characteristics, it will affect the power provided to the components of the integrated circuit. For example, because the power distribution network has resistance, it will cause a voltage drop across the network, and the voltage provided to the integrated circuit components will be somewhat less than the voltage at the contacts to the external power source. It is also important to note that the power distribution network consists of many components, and that variations in the resistance of each component may affect the resistance between the external contacts and the on-chip components of the integrated circuit. This effect is greatest in the area of the chip nearest the component, but extends outward from this point to some degree. As a result, manufacturing variations that affect the resistance of the power distribution network components may affect the uniformity of the network's resistance across the integrated circuit, as well as the uniformity of the voltage across the integrated circuit chip.

Variations in the uniformity of the voltage supplied to the integrated circuit may cause the voltage supplied at one point on the chip may therefore be lower than the voltage supplied at another point on the chip. If the reduced voltage at the first point is less than a voltage at which the integrated circuit is designed to operate, the integrated circuit may malfunction. Conventionally, this problem is addressed by increasing the voltage applied to the external contacts of the power distribution network, so that the voltage supplied at each point on the integrated circuit chip is no less than the design voltage. While this reduces the probability of a malfunction resulting from a below-minimum voltage at the first point, it is expensive in terms of the overall power budget, since other points will operate at voltages which are higher than necessary.

An alternative approach to solving this problem was proposed by Takase in U.S. patent application Ser. No. 11/684,181. In this alternative approach, the voltage is not increased across the entire chip to compensate for the reduced voltage at the first point, but is instead selectively increased to affect only the area around the first point. This is accomplished by splitting the power plane through which the external voltage is applied to the power distribution network into separate sections, and applying different external voltages to the different sections. One of the power plane sections which corresponds to the area around the first point is coupled to a higher voltage than the other sections so that the voltage in the area around the first point will be increased with respect to the other areas of the chip.

In order for this approach to be implemented, however, it is necessary to be able to identify the area in which the chip voltage resulting from a uniformly applied external voltage is too low. It would therefore be desirable to provide systems and methods for identifying areas of the integrated circuit chip for which the voltages supplied by the power distribution network are too low (or too high) so that the power plane can be separated into appropriate sections, enabling different voltages to be applied to different parts of the power distribution network to compensate for the variations.

### SUMMARY OF THE INVENTION

One or more of the problems outlined above may be solved by the various embodiments of the invention. Broadly speaking, the invention includes systems and methods for determining local voltages provided by a power distribution network to an integrated circuit chip by applying an external voltage to a power distribution network, firing a set of current sources distributed across the chip and measuring local voltages on the chip.

One embodiment comprises a method implemented in an integrated circuit including the steps of applying a substantially uniform voltage to the power plane of the chip's power distribution network, firing a set of current sources that are distributed across the chip, and determining voltages at multiple locations on the chip. The locations at which the voltages are measured may or may not be the same as the locations of the current sources. The measured voltages may be used to identify non-uniformities in the voltage applied across the chip, as well as to determine local differences in the resistance of the power distribution network.

The current sources may consist, for example, of a clock tree carrying a free running clock signal or a set of structures that are intended solely for the purpose of uniformly drawing current through the power distribution network. The local voltages on the chip may, for instance, be measured using voltage controlled oscillators (VCO's.) Counters may be provided to count the oscillations in the output signals of the VCO's, and registers or latches may be provided to store the numbers of oscillations that are counted in a predetermined interval. In one embodiment, the latches are contained in scan chains that allow the contents of the latches to be read out of the device.

After the local voltages on the integrated circuit have been determined, areas of the chip having non-uniformities, such as below-nominal voltage, may be identified. The power plane may be divided into sections (one or more corresponding to the identified areas of the chip,) and voltages applied to the different sections may be adjusted to compensate for the previously determined on-chip voltages.

Another embodiment comprises a system including an integrated circuit chip having a power distribution network. Current sources are provided on the chip to draw current substantially uniformly through the power distribution network. Voltage measurement units are also provided to measure local voltages at multiple locations on the chip. As in the method described above, the current sources may comprise a variety of structures, such as a clock tree carrying a free running clock or a set of special-purpose components which serve only to draw current uniformly through the power distribution network. Similarly, the voltage measurement units may comprise a variety of structures. In one embodiment, voltage controlled oscillators (VCOs) are used to generate signals that oscillate at a frequency corresponding to the measured voltage. Counters are used to count the number of oscillations in a known interval, and registers are used to store the counter values.

Numerous additional embodiments are also possible.

### BRIEF DESCRIPTION OF THE DRAWINGS

Other objects and advantages of the invention may become apparent upon reading the following detailed description and upon reference to the accompanying drawings.

FIG. 1 is a diagram illustrating a perspective view of several of the metal layers of a typical power distribution network.

FIG. 2 is a diagram illustrating a cross-sectional view of the structure of a typical power distribution network.

FIG. 3 is a diagram illustrating the effect of locally varying component resistances in a power distribution network.

FIG. 4 is a diagram illustrating the use of a divided power plane to achieve localized increases in voltage at the silicon level of an integrated circuit.

FIG. 5 is a flow diagram illustrating method for determining the chip-level voltage variations in an integrated circuit in accordance with one embodiment.

FIG. 6 is a diagram illustrating the structure of an exemplary current source in accordance with one embodiment.

FIG. 7 is a diagram illustrating a structure for measuring a voltage using a voltage controlled oscillator in accordance with one embodiment.

FIG. 8 is a diagram illustrating the latches of a set of LBIST scan chains and the mechanism for storing oscillation counts in the latches in accordance with one embodiment.

While the invention is subject to various modifications and alternative forms, specific embodiments thereof are shown by way of example in the drawings and the accompanying detailed description. It should be understood that the drawings and detailed description are not intended to limit the invention to the particular embodiments which are described. This disclosure is instead intended to cover all modifications, equivalents and alternatives falling within the scope of the present invention as defined by the appended claims.

### DETAILED DESCRIPTION OF EXEMPLARY EMBODIMENTS

One or more embodiments of the invention are described below. It should be noted that these and any other embodiments described below are exemplary and are intended to be illustrative of the invention rather than limiting.

Broadly speaking, the invention includes systems and methods for determining local voltages provided by a power distribution network to an integrated circuit chip by applying an external voltage to a power distribution network, firing a set of current sources distributed across the chip and measuring local voltages on the chip.

In one embodiment, a set of current sources are implemented in an integrated circuit. These current sources are intended to draw current uniformly through the power distribution network which provides power to the integrated circuit chip. The current sources may, for instance, be part of a clock tree which distributes a clock signal throughout the integrated circuit, or multiple individual structures which are intended only for the purpose of uniformly drawing current through the power distribution network.

A set of voltage measurement units are also implemented on the integrated circuit chip. These voltage measurement units are intended to make local measurements of the voltage(s) applied to the integrated circuit chip. In one embodiment, the voltage measurement units consist of voltage controlled oscillators (VCO's.) The frequency of oscillation of each VCO is proportional to the locally applied voltage. The number of oscillations in the output signal of each VCO is therefore counted to determine the local voltage. This number may be stored in a register on the chip which can be read by a user. The register may, for example, consist of a dedicated register or a set of latches in a scan chain.

In the local voltages corresponding to the uniformly applied external voltage have been determined, non-uniformities (e.g., local variations that fall below a nominal design voltage) can be identified, and the externally applied voltage can be modified to compensate for the on-chip voltages.)

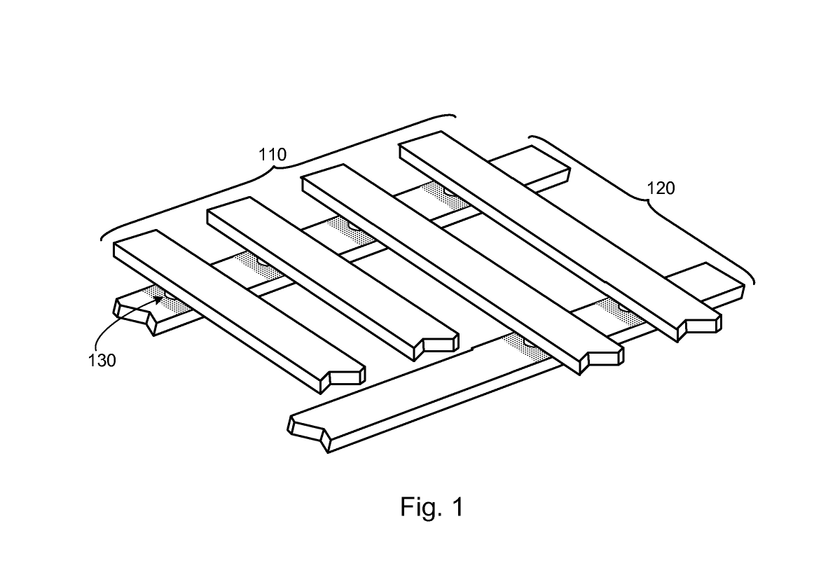

Before describing the exemplary embodiments of the invention in detail, it will be helpful to examine the structure of the power distribution network which is to be modeled. As noted above, the power distribution network consists of various layers that form and interconnecting network extending from an external power source to the various on-chip components of the integrated circuit. Referring to FIG. 1, a diagram providing a perspective view of several of these layers is shown. More specifically, FIG. 1 shows two of the metal layers in the network. It can be seen that the upper metal layer 110 consists of a series of traces that are oriented in a first direction. A lower metal layer 120 has a similar series of traces, but the traces are oriented in a second direction which is perpendicular to the first direction. Between layers 110 and 120 is a layer of vias 130 that connect traces in layer 110 to traces in layer 120. By in the traces of the different metal layers, power can be distributed to many different points across the area of the integrated circuit.

It should be noted that, for the purposes of this disclosure, references to the “top” or “upper” part of the power distribution network mean the part nearest the external power source. References to the “bottom” or “lower” part of the power distribution network mean the part nearest the silicon of the integrated circuit chip. It should also be noted that while the exemplary embodiments described herein concern a silicon-based integrated circuit, alternative embodiments may be implemented in integrated circuits that are constructed using other semiconductor materials. References herein to silicon should therefore be construed to include other types of semiconductor materials as well.

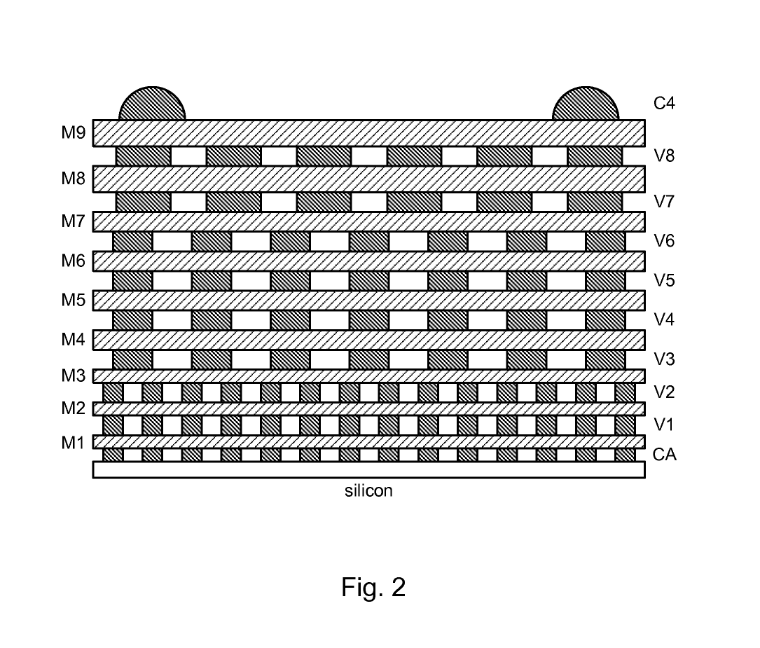

Referring to FIG. 2, a diagram illustrating a cross-sectional view of the structure of the power distribution network is shown. The power distribution network depicted in this figure includes nine different metal layers, indicated as M1-M9. (While the traces of successive metal layers are oriented in different directions, these layers are depicted as solid, unbroken layers for purposes of clarity.) Between the metal layers are eight layers of vias, indicated as V1-V8. The traces of layer M1 are connected to the traces of layer M2 by vias in layer V1, traces of layer M2 are connected to traces of layer M3 by vias in layer V2, and so on. There are also two layers (CA and C4) which consist of contacts. Contact layer CA connects traces of metal layer M1 to components on the surface of the integrated circuit chip, while contact layer C4 connects traces of metal layer M9 to the external power source. It should be noted that the figure depicts only a small portion of the power distribution network, and that the network may include many more contacts, traces and vias.

It can be seen that there are some differences between the various layers shown in FIG. 2. For example, the metal layers have several different thicknesses. Likewise, the vias in the different layers have varying sizes and spacings. The contacts in layer CA also have different sizes and spacings than the contacts in layer C4. These differences may result from a variety of design considerations. For example, the traces in metal layer M9 may have to carry larger currents than the traces of lower metal layers, so it may be necessary to make these traces wider and more thick than the traces in the lower layers. The same may be true of the contacts and vias in the other layers. As a result of these differences, each layer may have different electrical characteristics. For instance, because the contacts in layer C4 may be fewer in number and larger than the contacts in layer CA, the contacts in layer C4 may have a greater resistance per unit area than the contacts in layer CA.

As pointed out above, the characteristics of the power actually provided to components of the integrated circuit are not identical to the characteristics of the power applied by the power source at the external (C4) contacts of the power distribution network because of the electrical characteristics of the power distribution network itself. For instance, there may be defects in the traces or vias that cause them to have resistance values which are higher or lower than nominal design values. These variations in the resistances of the traces and/or vias result then cause variations in the resistance of the power distribution network. Moreover, because the defects (or manufacturing variations) in the components may not be homogeneous throughout the layers of the power distribution network, there may be local variations in the resistance of the network.

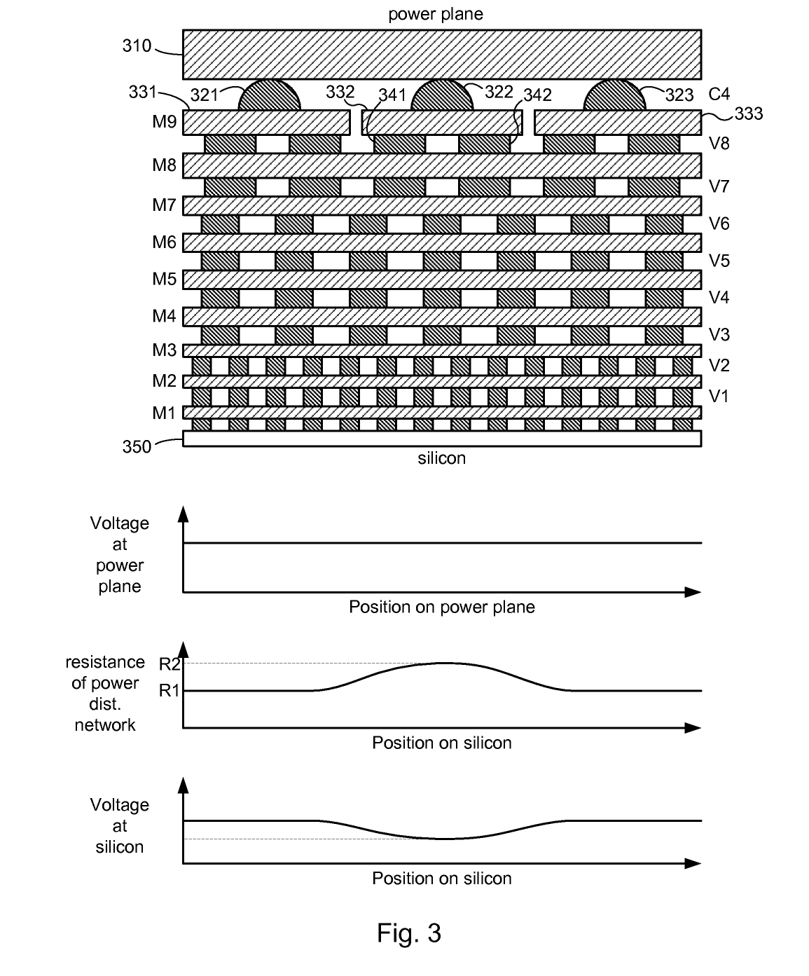

Referring to FIG. 3, a diagram illustrating the effect of locally varying component resistances is shown. At the top of this figure, a side view of the power distribution network is shown. This diagram is similar to the diagram of FIG. 2, except that a power plane 310 is shown connected to C4 contacts 321-323, and the metal traces (331-333) of the top metal layer (M9) are separately depicted. (As noted above, the traces of successive metal layers are oriented in different directions.)

The bottom portion of FIG. 3 includes three graphs. The first is a graph of the voltage at the power plane (310) as a function of position (left to right) on the power plane. The second is a graph of the resistance of the power distribution network as a function of position. This resistance is the overall resistance from the power plane to the corresponding position on the silicon of the integrated circuit. The third graph shows the voltage at the silicon as a function of position.

FIG. 3 assumes that one or more of the components near the center of the power distribution network have higher-than-nominal resistance values. For example, one or more of contact 322, trace 332, or the vias connected to it (e.g., 341, 342) may have resistance values which are substantially higher than nominal. As a result of these higher-than-nominal values, the resistance of the power distribution network (between power plane 310 and silicon 350) will be higher near the above-nominal components, and lower elsewhere. This is illustrated in the resistance graph of FIG. 3. This graph shows that the resistance of the power distribution network is approximately R1 across most of the network, but is higher near the above-nominal components (at the center of the graph.) If a power source is connected to the power plane and a constant voltage is applied across the power distribution network (as shown on the power plane voltage graph,) the voltage that is supplied to the integrated circuit components on the chip will be lower in the region local to the above-nominal components (as shown on the silicon voltage graph at the bottom of FIG. 3.) The dip in voltage results from the higher resistance of the power distribution network in the region of the above-nominal components (as shown in the resistance graph of FIG. 3.)

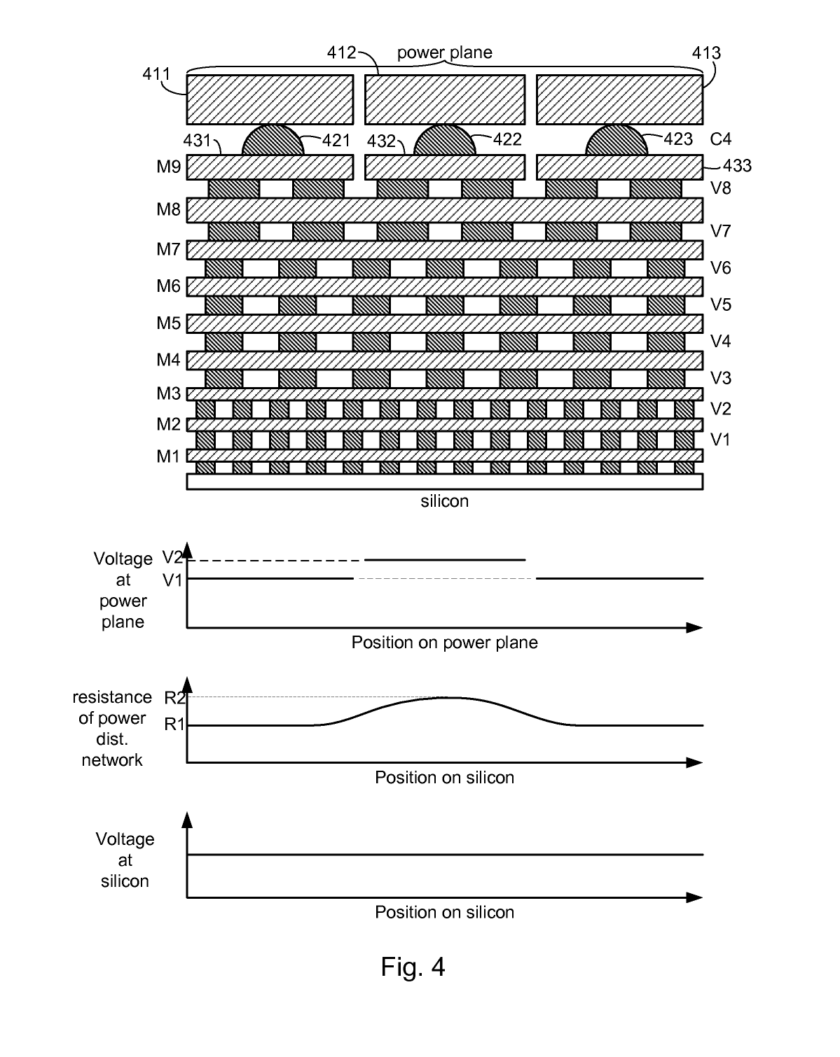

Localized variations in the voltage supplied at the chip can be compensated by, for example, dividing the power plane into sections and applying different voltages to different sections. Referring to FIG. 4, a diagram illustrating the use of a divided power plane to achieve localized increases in voltage is shown. FIG. 4 is similar to FIG. 3, showing a side view of a power distribution network, and a set of voltage and resistance curves corresponding to the power distribution network. In FIG. 4, the power plane is divided into several separate pieces (e.g., 411-413.) Each of the pieces of the power plane is connected to a corresponding set of contacts (e.g., 421-423) and traces (e.g., 431-433.) Because the pieces of the power plane are separate, different voltages can be applied to the different pieces.

As noted above, the power-plane is divided into separate pieces (e.g., 411-413.) “Separate,” as used here, means the pieces of the power plane are not directly connected to each other. The separate pieces of the power plane are not electrically isolated, due to the fact that they are indirectly connected through the power distribution network. Assuming again that one or more of the components in the center of the power distribution network (e.g., contact 422 or trace 432) have resistances that are substantially above their nominal values, the overall resistance of the power distribution network will be locally higher near these components. This is illustrated in the resistance graph (the middle graph at the bottom of FIG. 4.) In order to compensate for this locally increased resistance, a first voltage (V1) is applied to power plane sections 411 and 413, while a second, higher voltage (V2) is applied to power plane section 412. This is illustrated in the power plane voltage graph (the top graph at the bottom of FIG. 4.) Because the higher voltage is applied only to the portion of the power distribution network that exhibits an increased resistance, relative to the remainder of the network, the higher voltage drop across the network is compensated, resulting in a more constant voltage across the entire integrated circuit chip (as shown in the bottom graph of FIG. 4.) It should be noted that the voltage at the silicon is depicted as being constant for purposes of simplicity, and that there may still be some variations across the chip.

Because the variations in the resistance of the power distribution network, and the corresponding variations in voltage at the silicon of the integrated circuit chip, will generally be different between one device and the next, the power plane cannot be divided in the same manner for each device. It will instead be necessary for each device to determine the corresponding silicon-level voltage variations so that appropriate compensation can be achieved through splitting the power plane and applying different voltages to different sections of the power plane.

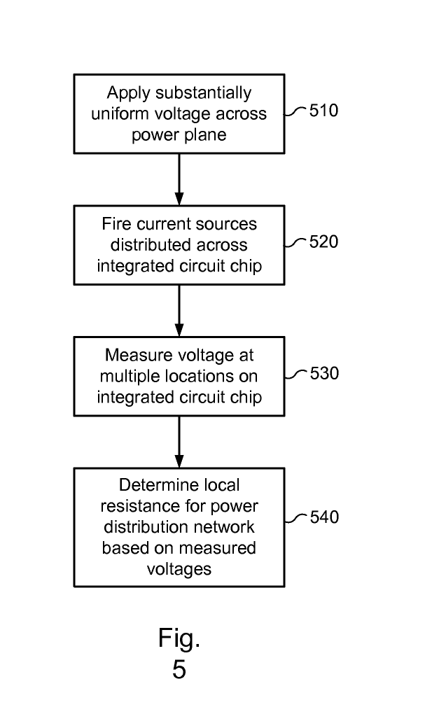

Referring to FIG. 5, an exemplary method for determining the chip-level voltage variations in an integrated circuit is shown. FIG. 5 is a flow diagram illustrating the steps of the exemplary method. In this figure, a substantially uniform voltage is applied across the power plane of a power distribution network (510.) The power plane may, for example, be a unitary component to which a single voltage is applied in accordance with conventional techniques. A plurality of current sources which are distributed across the integrated circuit chip, such as the components of a free running clock tree, are then fired (520.)

It should be noted that “current source,” as used herein, refers to a device which is designed to cause a certain amount of current to flow through it, and is not intended to imply that the current originates at this device. A current source could alternatively be referred to as a current sink or current regulator.

As each current source draws current through the corresponding portion of the power distribution network, a voltage drop occurs due to the resistance of the network, causing the voltage at the integrated circuit chip to be less than the voltage which is applied to the power plane. The voltage at the chip is therefore measured at different locations across the chip corresponding to the current sources (530.) Based on the measured voltages, the local resistance of the power distribution network can then be calculated (540.)

In the first step of this method, a voltage from an external power source is applied substantially uniformly across the power plane of the power distribution network. If the power plane is a unitary (one-piece) component, this is simply a matter of applying the voltage conventionally to the power plane. Typically, the resistance of the power plane is very low, so simple connections to the external power source will provide a substantially uniform voltage across the power plane. If the power plane consists of multiple sections, the voltage applied to each section should be substantially the same. (“Substantially” is used here to indicate that the voltages applied to the different sections need not be exactly the same, but should be nearly so.) It should be noted that, in alternative embodiments, different voltages could be applied to different power plane sections, but it is contemplated that the use of the same voltage will simplify calculation of local power distribution network resistances, adjusted voltages required to achieve a uniform chip-level voltage, and the like.

After the external voltage has been applied to the power plane, the current sources on the integrated circuit chip are fired. That is, the current sources are operated so that current flows through them, hence through the power distribution network. The current sources will be discussed in more detail below. The purpose of firing the current sources is to draw the same amount of current through each part of the power distribution network. The voltage drop at each point on the integrated circuit chip is therefore proportional to the local resistance of the power distribution network at that point. The voltage which is applied to the chip at that point is the externally applied voltage, minus the voltage drop across the power distribution network. When these relationships have been determined, the voltages at the power plane can be altered (e.g., by dividing the power plan into separate sections and applying different voltages to different sections) to cause the voltages at the chip level to be more uniform, or to ensure that these voltages are greater than or equal to a nominal design voltage.

When the current sources are fired, the local voltages at the integrated circuit chip are measured. As noted above, the local on-chip voltage will be reduced from the externally applied voltage by the amount of the local voltage drop across the power distribution network. The mechanism by which the local voltages are determined is discussed in more detail below. The local voltages are determined at multiple locations on the integrated circuit chip. While the local voltages may be determined at the location of each current source, this is not necessarily the case. The local voltages may simply be measured at a number of locations which are relatively evenly distributed across the chip. The locally measured voltages will effectively provide a map of the chip, showing areas in which the voltages vary and, possibly, fall below a nominal design voltage which is required for proper operation of the functional components on the chip (i.e., the components that perform the desired end-functions of the device, as opposed to components that serve test or diagnostic purposes.)

After the local voltages at the integrated circuit chip have been measured, the local resistance across the power distribution network can be calculated from the current drawn by the current sources. This current can, for example, be measured at the voltage regulator which is used to generate the externally applied voltage. Based on the local resistance, areas of higher resistance can be identified and, if necessary, the power plane can be divided so that higher voltages can be applied in these areas. The application of these higher voltages can compensate for the increased local voltage drops across the power distribution network, resulting in the increase of corresponding local voltages to acceptable levels.

As mentioned above, the current sources are used to draw current relatively evenly through the power distribution network. The current sources should therefore be substantially evenly distributed across the integrated circuit chip. In one embodiment, the existing clock distribution system of the integrated circuit tree may serve as the current source(s). Because many of the components in the integrated circuit typically require a clock system to synchronize their operation, a clock distribution system (or “clock tree”) is used to distribute the clock signal to the various components. Typically, the clock tree covers most, if not all, of the integrated circuit. The clock tree is therefore appropriately located (i.e., it is distributed relatively evenly across the integrated circuit.) Further, if the clock tree is used to simply distribute a free-running clock signal (without operating the functional components of the integrated circuit,) the operation of the clock tree should draw current in a relatively homogeneous fashion across the entire integrated circuit.

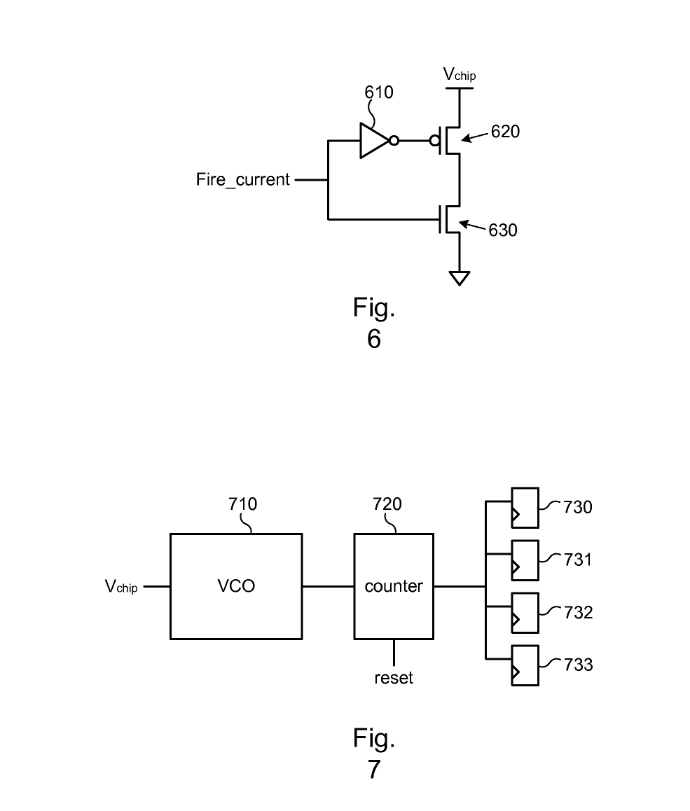

In an alternative embodiment, individual current sources can be incorporated into the design of the device specifically for the purpose of drawing current evenly through the power distribution network. The structure of an exemplary current source is illustrated in FIG. 6. Multiple instances of this current source can be evenly distributed across the integrated circuit chip. The current source in FIG. 6 consists of a PMOS transistor 620, an NMOS transistor 630 and an inverter 610. Transistors 620 and 630 are serially arranged between a source voltage (i.e., the voltage provided to the integrated circuit chip through the power distribution network) and ground. When both transistors are switched off, no current flows through them. When both transistors are switched on, current is allowed to flow through the transistors to ground. A signal (Fire_current) is provided to switch the transistors on or off. Fire_current is applied directly to the gate of transistor 630, while the inverse of the signal (generated by inverter 610) is applied to the gate of transistor 620.

As noted above, the voltage at the integrated circuit chip may be determined in a variety of ways. In one embodiment, the voltage is measured using a voltage controlled oscillator (VCO.) An exemplary voltage measurement unit which is implemented using a VCO is shown in FIG. 7. The structure of FIG. 7 includes a VCO 710, a counter 720 and a register (e.g., a set of latches 730-733.) This structure is configured to measure the voltage at one point on the integrated circuit chip, and is replicated as necessary to determine the voltages at desired points across the chip.

VCO 710 is controlled by an input voltage (Vchip) that is provided to the integrated circuit chip at the location of the VCO. The VCO generates an output signal that oscillates at a frequency corresponding to the input voltage. The frequency of the output signal generated by VCO 710 varies according to a function which has a linear region in which the frequency is proportional to the input voltage. VCO 710 is designed so that the expected range of input voltages falls within the range that is within the linear region. The input voltage can therefore be determined simply by multiplying the frequency of the output signal by a proportionality constant.

In the embodiment of FIG. 7, the output signal generated by VCO 710 is provided to a counter 720. Counter 720 is configured to count the number of oscillations that occur in the output signal in a predetermined interval. A reset signal which is provided to counter 720 can be asserted to reset the counter to 0 at the beginning of the interval. At the end of the interval, the number can be clocked into latches 730-733. The number can be stored in the latches until it can be read out by the user.

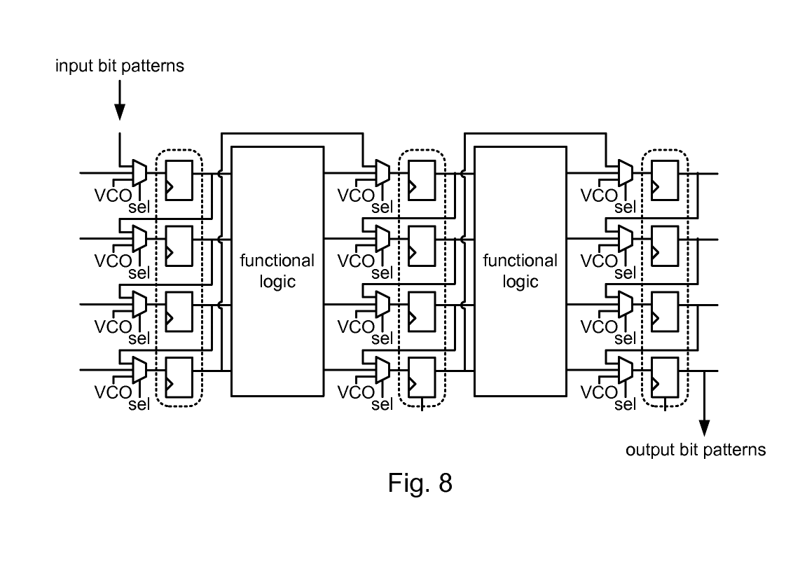

In one embodiment, the voltage measurement structure makes use of existing latches to store the value from the oscillation counter. More specifically, the structure uses the latches of existing LBIST (logic built-in self test) scan chains. Referring to FIG. 8, a diagram illustrating the latches of the scan chains and the mechanism for storing the oscillation counts in them is shown. A scan chain is a series of latches in an integrated circuit into which data can be loaded or “scanned.” The data is then propagated through some functional logic and captured in the latches of a subsequent scan chain. Finally, the captured data is shifted (scanned) out of the latched and examined in some manner to determine whether the functional logic operated properly. The scan and capture functions of the latches are determined by controlling a multiplexer to select either the output of a preceding latch or the output of the functional logic as the input to the latch.

In the present embodiment, the multiplexer is configured to accept a third input. This input is received from an oscillation counter. Thus, a set of the scan chain latches in FIG. 8 (indicated by the dashed lines) can serve as the latches (730-733) in FIG. 7. The multiplexer preceding the scan chain latch simply has to select the counter output instead of the functional logic or preceding latch outputs. After the oscillation counter data has been stored in the latches, it can be scanned out of the latches in the same way the output of the functional logic is scanned out for normal LBIST testing. It should also be noted that non-LBIST scan chains can be used for this purpose. For example, some integrated circuits incorporate a JTAG diagnostic scan chain which is used to load data into, and read data from, certain registers in the integrated circuit. These scan chains would be used in the same manner described above.

It should be noted that alternative embodiments of the invention may include many variations of the features disclosed above. For example, many other mechanisms for drawing current through the power distribution network, or for measuring the voltages at the integrated circuit chip may be used. Further, the voltage information determined according to the disclosed methods may be used for purposes other than the correction of non-uniformities. It is contemplated that many such variations will be apparent to a person of ordinary skill upon reading the present disclosure.

Those of skill in the art will understand that information and signals described herein may be represented using any of a variety of different technologies and techniques. For example, data, information, signals, bits, symbols, and the like that may be referenced throughout the above description may be represented by voltages, currents, electromagnetic waves, magnetic fields or particles, or any combination thereof. The information and signals may be communicated between components of the disclosed systems using any suitable transport media, including wires, metallic traces, vias, and the like.

The various illustrative logical blocks, modules, and circuits described in connection with the embodiments disclosed herein may be implemented or performed with application specific integrated circuits (ASICs), field programmable gate arrays (FPGAs) or other logic devices, discrete gates or transistor logic, discrete hardware components, or any combination thereof designed to perform the functions described herein.

The steps of a method or algorithm described in connection with the embodiments disclosed herein may be embodied directly in hardware, in software (program instructions) executed by a processor or other controller, or in a combination of the two. Software may reside in RAM memory, flash memory, ROM memory, EPROM memory, EEPROM memory, registers, hard disk, a removable disk, a CD-ROM, or any other suitable storage medium.

The benefits and advantages which may be provided by the present invention have been described above with regard to specific embodiments. These benefits and advantages, and any elements or limitations that may cause them to occur or to become more pronounced are not to be construed as critical, required, or essential features of any or all of the claims. As used herein, the terms “comprises,” “comprising,” or any other variations thereof, are intended to be interpreted as non-exclusively including the elements or limitations which follow those terms. Accordingly, a system, method, or other embodiment that comprises a set of elements is not limited to only those elements, and may include other elements not expressly listed or inherent to the claimed embodiment.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein and recited within the following claims.

What is claimed is:

1. A method comprising:
applying a substantially uniform voltage to a power plane of a power distribution network connected to an integrated circuit chip;
firing a plurality of current sources that are distributed across the chip; and
determining voltages at multiple locations on the chip.

2. The method of claim 1, wherein the locations comprise locations of each of the current sources.

3. The method of claim 1, wherein firing the current sources comprises enabling a free running clock on a clock tree that is distributed across the chip and inhibiting operation of functional logic in the integrated circuit.

4. The method of claim 1, wherein determining voltages at the chip associated with each of the current sources comprises operating a plurality of voltage controlled oscillators (VCO's) associated with the current sources and determining a frequency of oscillation and corresponding voltage for each of the VCO's.

5. The method of claim 4, wherein determining the frequency of oscillation for each VCO comprises counting a number of oscillations that occur in a predetermined interval.

6. The method of claim 5, further comprising reading out the number of oscillations associated with each VCO via a scan chain in the integrated circuit.

7. The method of claim 1, further comprising determining a localized resistance of the power distribution network associated with each of the current sources.

8. The method of claim 1, further comprising identifying an area of the chip for which the voltages associated with the current sources are less than a nominal design voltage.

9. The method of claim 8, further comprising dividing the power plane into a plurality of separate sections, wherein at least one of the sections is associated with the identified area.

10. The method of claim 9, further comprising determining one or more voltages which, when applied to the sections associated with the identified area, produce voltages at the chip which are greater than or equal to the nominal design voltage.

11. A system comprising:
an integrated circuit chip
a power distribution network coupled to the chip
one or more current sources on the chip, wherein the current sources are configured to draw current substantially uniformly through the power distribution network
one or more voltage measurement units configured to measure local voltages at multiple locations on the chip.

12. The system of claim 11, wherein the voltage measurement units are configured to measure local voltages at locations corresponding to each of the current sources.

13. The system of claim 11, wherein the current sources comprise a clock tree that is distributed across the chip.

14. The system of claim 11, wherein each voltage measurement unit comprises a voltage controlled oscillator (VCO) configured to generate an output signal having a frequency of oscillation corresponding to a measured voltage.

15. The system of claim 14, wherein each voltage measurement unit further comprises a counter configured to count a number of oscillations of the VCO output signal that occur in a predetermined interval.

16. The system of claim 15, further comprising a register configured to store the number of oscillations counted by the counter.

17. The system of claim 16, wherein the register comprises one or more latches in a scan chain that is implemented in the integrated circuit.

18. The system of claim 17, wherein the scan chain comprises a logic built-in self-test (LBIST) scan chain configured to function alternately in a first mode or in a second mode, wherein in the first mode one or more of the latches in the scan chain stores the number of oscillations counted by the counter, and wherein in the second mode the scan chain stores either LBIST test patterns or LBIST test results.

19. The system of claim 17, wherein the scan chain comprises a diagnostic scan chain.

20. The system of claim 11, further comprising a unitary power plane coupled to the power distribution network and an external power source coupled to the power plane.
